(19) United States
(12) Patent Application Publication
(10) Pub. No.: US 2011/0088768 A1
(43) Pub. Date: Apr. 21, 2011

(54) METHOD OF ANNEALING CADMIUM TELLURIDE PHOTOVOLTAIC DEVICE

(75) Inventors: Markus Gloeckler, Perrysburg, OH (US); Rick C. Powell, Ann Arbor, MI (US)

(73) Assignee: First Solar, Inc., Perrysburg, OH (US)

(21) Appl. No.: 12/903,800

(22) Filed: Oct. 13, 2010

Related U.S. Application Data
(60) Provisional application No. 61/251,108, filed on Oct. 13, 2009.

(51) Int. Cl. H01L 31/0224; H01L 31/0352; H01L 31/0272

(52) U.S. Cl. 136/256; 438/94; 136/260; 438/95; 257/E31.032

(57) ABSTRACT

A method of manufacturing a photovoltaic device may include forming a cadmium zinc sulfide layer on a substrate; depositing a cadmium telluride layer on the cadmium zinc sulfide layer; contacting a cadmium chloride to the cadmium telluride layer; and annealing one or more layers, where the one or more layers includes at least the cadmium telluride layer.

### CLAIM FOR PRIORITY

This application claims priority under 35 U.S.C. §119(e) to U.S. Provisional Patent Application Ser. No. 61/251,108 filed on Oct. 13, 2009, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

### DETAILED DESCRIPTION

A method of manufacturing a photovoltaic device may include forming a cadmium zinc sulfide layer on a substrate; depositing a cadmium telluride layer on the cadmium zinc sulfide layer; contacting a cadmium chloride to the cadmium telluride layer; and annealing one or more layers, where the one or more layers includes at least the cadmium telluride layer.

The method may have various optional features. For example, the annealing may include heating at least the cadmium telluride layer above about 380 C. The annealing may include heating at least the cadmium telluride layer in a range of about 400 C to about 600 C. The annealing may include heating at least the cadmium telluride layer in a range of about 410 C to about 500 C. The annealing may include heating at least the cadmium telluride layer above about 400 C. The annealing may include heating at least the cadmium telluride layer below about 600 C. The annealing may include heating at least the cadmium telluride layer for about 5 to about 60 minutes. The annealing may include heating at least the cadmium telluride layer for about 10 to about 50 minutes. The annealing may include heating at least the cadmium telluride layer for about 20 to about 30 minutes. The substrate may include a transparent conductive oxide stack on a soda-lime glass, where the transparent conductive oxide stack includes one or more barrier layers, a transparent conductive oxide layer on the one or more barrier layers, and a buffer layer on the transparent conductive oxide layer. The contacting may include physical vapor deposition. The contacting may occur in a vacuum.

A photovoltaic device may include a cadmium telluride layer on a cadmium zinc sulfide layer, where the cadmium telluride layer is in at least partial contact with a cadmium chloride. The cadmium zinc sulfide layer may have about 20 to about 40% zinc. The photovoltaic device may include a cadmium zinc telluride layer between the cadmium zinc sulfide layer and the cadmium telluride layer. The cadmium zinc telluride layer may have a zinc content of about 2% to about 10%. The cadmium zinc telluride layer may have a zinc content of about 4% to about 8%. The cadmium zinc telluride layer may have a zinc content in a range of about 5% to about 6%. The photovoltaic device may include a transparent conductive oxide stack on a substrate, where the transparent conductive oxide stack includes one or more barrier layers, a transparent conductive oxide layer on the one or more barrier layers, and a buffer layer on the transparent conductive oxide layer, where the cadmium zinc sulfide layer is positioned on the transparent conductive oxide stack.

A photovoltaic device can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers.

Photovoltaic devices can be formed on optically transparent substrates, such as glass. Because glass is not conductive, a transparent conductive oxide (TCO) layer can be deposited between the substrate and the semiconductor bi-layer. A buffer layer can be deposited between the TCO layer and the semiconductor window layer. Additionally, a barrier layer can be incorporated between the substrate and the TCO layer to lessen diffusion of sodium or other contaminants from the substrate to the semiconductor layers, which could result in degradation and delamination.

A cadmium zinc sulfide may be deposited onto the TCO stack to serve as a window layer. Cadmium zinc sulfide has proven more robust than cadmium sulfide for its ability to withstand high anneal temperatures during cadmium chloride annealing of the absorber layer, which can improve crystalline quality and transport properties in cadmium telluride. Excessive temperatures can cause interdiffusion in conventional cadmium sulfide/cadmium telluride structures, thereby disturbing the conformity of the cadmium sulfide layer. The cadmium zinc sulfide may be deposited using any suitable technique, including any of those described in Provisional U.S. Patent Application Ser. No. 61/225,013 filed on Jul. 13, 2009, which is hereby incorporated by reference in its entirety.

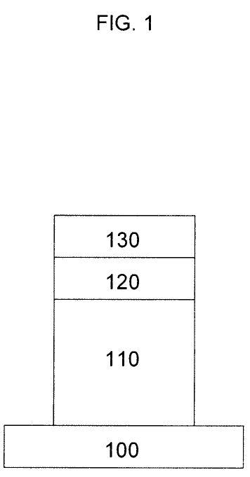

Referring to FIG. 1, a cadmium telluride layer 130 can be deposited on a cadmium zinc sulfide layer 120. Cadmium telluride layer 130 can be deposited using any suitable means, including vapor transport deposition. Cadmium zinc sulfide layer 120 may be deposited on transparent conductive oxide stack 110. Cadmium zinc sulfide layer 120 may be deposited or formed using any suitable process. Transparent conductive oxide stack 110 may be deposited on substrate 100, which may include any suitable material, including glass, for example, soda-lime glass.

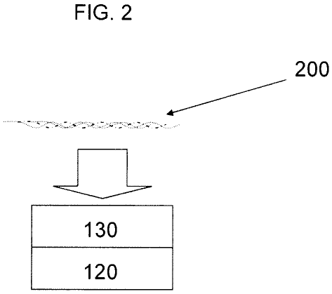

Following deposition, the device layers may undergo cadmium chloride treatment, thereby increasing grain size and improving device efficiency. Referring to FIG. 2, by way of example, a cadmium chloride 200 can be contacted to cadmium telluride layer 130. Cadmium chloride 200 can be contacted using any suitable means, including, for example, physical vapor deposition. Cadmium chloride 200 can be contacted under any suitable conditions, for example, under any suitable pressure, such as under reduced pressure, or in a vacuum. Cadmium chloride 200 can be a gas. Cadmium chloride treatment can occur following an anneal step, or directly following deposition of one or more device layers, which may or may not occur at a high temperature. Following deposition of cadmium chloride 200, the device layers can be annealed (for a first or second time) at a higher temperature than is typically used for devices without cadmium zinc sulfide. For example, cadmium telluride layer 130 and cadmium zinc sulfide layer 120 can be heated at a temperature above about 380 C, for example, in a range of about 400 C to about 800 C, about 500 C to about 700 C, about 550 C to about 650 C, more than about 400 C, or less than about 600 C. Photovoltaic devices fabricated using the methods disclosed herein may yield a higher efficiency than conventional devices when exposed to the sun (about 10% to about 15%, for example, about 12% to about 14%).

Following deposition and anneal, a back contact metal may be deposited onto the cadmium telluride layer. A back support may be deposited onto the back contact metal. The back support may include any suitable material, including a glass, for example, a soda-lime glass.

Photovoltaic devices/modules fabricated using the methods discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of manufacturing a photovoltaic device, the method comprising:
forming a cadmium zinc sulfide layer on a substrate;
depositing a cadmium telluride layer on the cadmium zinc sulfide layer;
contacting a cadmium chloride to the cadmium telluride layer; and
annealing one or more layers, the one or more layers comprising at least the cadmium telluride layer.

2. The method of claim 1, wherein the annealing comprises heating at least the cadmium telluride layer above about 380 C.

3. The method of claim 2, wherein the annealing comprises heating at least the cadmium telluride layer in a range of about 400 C to about 600 C.

4. The method of claim 3, wherein the annealing comprises heating at least the cadmium telluride layer in a range of about 410 C to about 500 C.

5. The method of claim 1, wherein the annealing comprises heating at least the cadmium telluride layer above about 400 C.

6. The method of claim 1, wherein the annealing comprises heating at least the cadmium telluride layer below about 600 C.

7. The method of claim 1, wherein the annealing comprises heating at least the cadmium telluride layer for about 5 to about 60 minutes.

8. The method of claim 7, wherein the annealing comprises heating at least the cadmium telluride layer for about 10 to about 50 minutes.

9. The method of claim 8, wherein the annealing comprises heating at least the cadmium telluride layer for about 20 to about 30 minutes.

10. The method of claim 1, wherein the substrate comprises a transparent conductive oxide stack on a soda-lime glass, the transparent conductive oxide stack comprising one or more barrier layers, a transparent conductive oxide layer on the one or more barrier layers, and a buffer layer on the transparent conductive oxide layer.

11. The method of claim 1, wherein the contacting comprises physical vapor deposition.

12. The method of claim 11, wherein the contacting occurs in a vacuum.

13. A photovoltaic device, comprising a cadmium telluride layer on a cadmium zinc sulfide layer, wherein the cadmium telluride layer is in at least partial contact with a cadmium chloride.

14. The photovoltaic device of claim 13, wherein the cadmium zinc sulfide layer has about 20 to about 40% zinc.

15. The photovoltaic device of claim 13, further comprising a cadmium zinc telluride layer between the cadmium zinc sulfide layer and the cadmium telluride layer.

16. The photovoltaic device of claim 15, wherein the cadmium zinc telluride layer has a zinc content of about 2% to about 10%.

17. The photovoltaic device of claim 16, wherein the cadmium zinc telluride layer has a zinc content of about 4% to about 8%.

18. The photovoltaic device of claim 17, wherein the cadmium zinc telluride layer has a zinc content in a range of about 5% to about 6%.

19. The photovoltaic device of claim 13, further comprising a transparent conductive oxide stack on a substrate, the transparent conductive oxide stack comprising one or more barrier layers, a transparent conductive oxide layer on the one or more barrier layers, and a buffer layer on the transparent conductive oxide layer, wherein the cadmium zinc sulfide layer is positioned on the transparent conductive oxide stack.
